(19) United States
(12) Patent Application Publication
(10) Pub. No.: US 2017/0055106 A1
(43) Pub. Date: Feb. 23, 2017

(54) SECONDARY DATA COMMUNICATION METHODOLOGY FOR METROLOGICAL DEVICE AUGMENTATION

(71) Applicant: General Electric Company, Schenectady, NY (US)

(72) Inventors: Yakov Polishchuk, Niskayuna, NY (US); Robert William Tait, Niskayuna, NY (US); John Brandon Laflen, Niskayuna, NY (US); William Hendrix, Greenville, SC (US)

(21) Appl. No.: 14/829,113

(22) Filed: Aug. 18, 2015

(51) Int. Cl. H04W 4/00; G01R 19/25; G01B 3/18; G01B 3/28; H04B 1/3827; G01B 3/56

(52) U.S. Cl. CPC H04W 4/008; H04B 1/385; G01B 3/56; G01B 3/18; G01B 3/28; G01B 3/563; G01R 19/2503

(57) ABSTRACT

According to some embodiments, system comprises a metrological device operative to collect and transmit measurement data; and a hands-free communication device operative to receive the collected data and communicate the data to a user. Numerous other aspects are provided.

### BACKGROUND

Many known physical assets and physical systems require asset monitoring. Asset monitoring may involve the determination of asset status by identifying asset data including, for example, physical measurements related to assets or asset components, physical location or orientation of assets, and the presence or physical ability of assets. Asset data may be obtained using metrological inspection. The timeliness of the receipt and analysis of asset data may impact business performance.

Therefore, it would be desirable to provide an apparatus and method that provides asset data in a more timely fashion.

### BRIEF DESCRIPTION

According to some embodiments, a system includes a metrological device operative to obtain and transmit measurement data; and a hands-free communication device operative to receive the obtained data and communicate the data to a user.

According to some embodiments, a method includes obtaining measurement data with a metrological device; transmitting the obtained measurement data; receiving the obtained measurement data at a hands-free communication device; and communicating the obtained measurement data to a user.

A technical effect of some embodiments of the invention is an improved technique and system for asset monitoring. With this and other advantages and features that will become hereinafter apparent, a more complete understanding of the nature of the invention can be obtained by referring to the following detailed description and to the drawings appended hereto.

Other embodiments are associated with systems and/or computer-readable medium storing instructions to perform any of the methods described herein.

### DRAWINGS

FIG. 1 illustrates a system according to some embodiments.

FIG. 2 illustrates a flow diagram according to some embodiments.

FIG. 3 illustrates a block diagram according to some embodiments.

FIG. 4 illustrates a flow diagram according to some embodiments.

FIG. 5 illustrates a block diagram of a system according to some embodiments.

FIG. 6 illustrates a block diagram of a system according to some embodiments.

### DETAILED DESCRIPTION

Many known physical assets and physical systems require asset monitoring. Asset monitoring may involve the determination of asset status by identifying asset data including, for example, physical measurements related to assets or asset components, physical location or orientation of assets, and the presence or physical ability of assets. Asset data may be obtained using metrological inspection. The timeliness of the receipt and analysis of asset data may impact business performance.

As used herein, “metrological inspection” refers to the use of devices or tools to obtain asset data and, in particular, physical measurements. Asset data may describe physical measurements including, for example, distance, volume, pressure and velocity. Other physical measurements may be included. Alternatively, asset data may describe asset characteristics which may require analysis or extrapolation to determine physical measurements. For example, asset data may be optical data which includes a plurality of geographic coordinates in reference to an asset. The optical data may not be immediately discernible as useful physical measurements, but computation and extrapolation may yield physical measurements. Metrological inspection may involve the use of metrological inspection devices. Metrological inspection devices may include any device capable of facilitating metrological inspection including, for example, gauges, sensors and calipers.

Some metrological inspection devices may include computing devices capable of displaying asset data to a user display, storing asset data to a memory device, and transmitting asset data to other computing devices.

Many known physical systems and physical assets are monitored and inspected through taking a large plurality of asset data readings. Such monitoring and inspection may be time consuming.

Conventional metrological devices may include removable data displays for displaying the measured data that may be selectively connected to the metrological device. However, metrological devices may, at times, be used in hard to reach/see, remote, or difficult to access areas, where displayed data (e.g., via the metrological device or a hand-held device) is not easily seen. In these instances, the user may have to obtain the measurement, then extract the metrological device from the measurement area to read the measurement. After reviewing the measurement, the user may then decide to: 1. go back into the measurement area to repeat the measurement, 2. move on to the next measurement, or 3. the measurements are complete. The back-and-forth of the user may be time consuming.

Alternatively, in these instances, at least two users may be involved for complex measurement tasks, where one user obtains the measurements and a second user reviews the measurement(s) to make a determination based on the measurement (e.g., the measurement needs to be repeated, move on to the next measurement, or skip the next several measurements), and then relay further instructions to the first user taking the measurements.

Further, the raw data captured by the metrological device may not be useful to the user. The raw data may be sent to a processing platform to further process and analyze the data. However, the processing platform may be too big, out of reach, or simply inconvenient to be used as a data display. In instances involving these big, out of reach and/or inconvenient processing platforms, two users may be involved, as described above—a first user to take the measurements, and a second user to review the analyzed data and relay instructions to the first user.

Some embodiments provide a system and method for communicating raw (e.g., un-analyzed) data, taken with a metrological device, or data taken with a metrological device and subsequently analyzed “analyzed data,” to a hands-free communication device for communication with a user. For example, the hands-free communication device may be a wearable item such as a wrist-worn smart watch, a heads up display (HUD) (e.g., Google Glass), or a body-worn display; a detached display mounted or positioned somewhere other than the metrological device but easily accessible by the single user, a speaker that may be mounted or placed in the measurement environment, a light feedback module, or a haptic feedback module (e.g., vibration motor). Other suitable hands-free communication devices may be used.

Advantages of embodiments are that the data (raw or analyzed), and instructions (e.g., recommendations) may be communicated to a single user, as opposed to involving multiple users, and that the instructions may be communicated in situ, without having to remove the metrological device from the measurement area. Another advantage of embodiments, is the hands-free communication device may be more versatile and easier to use compared to displays that are too big, out of reach or inconvenient. Still another advantage of embodiments is providing at least one of analyzed data and recommendations to the user provides the user with more complete data, thereby allowing the user to make faster and more informed decisions. Embodiments allow the single user to focus more on the measurement task, rather than on trying to look at the metrological device to see the measurement, thereby making the user more focused on the measurement task.

As used herein, the terms “asset data” and “data,” as well as related terms refer to any data related to at least one physical state of at least one physical asset. Asset data may include, for example, physical measurements of distance, physical measurements of volume, physical measurements of pressure, physical measurements of temperature, location information, physical measurements of electrical current, and any other physical measurement which may be detected using a metrological sensing device. Asset data containing physical measurements may be referred to as “primary asset data.” Alternately, asset data may include, without limitation, “secondary asset data,” which may be used to determine physical measurements. For example, optical data produced by a borescope may present as a series of three-dimensional coordinates which can be processed to determine the physical characteristics of an asset. However, such optical data may not represent “primary asset data” within the meaning above unless such processing occurs. As used herein, this form of secondary asset data used to create physical measurements may be used interchangeably with primary asset data containing physical measurements.

As used herein, the term “metrological sensing device” or “metrological device” and related terms refers to tools, devices, and other apparatus capable of measuring or otherwise determining asset data. Although metrological devices may be manual or electronic, the metrological devices used in conjunction with the systems and methods described herein are capable of transmitting asset data to another device. In some examples, the metrological device may include a display, a processor and a memory device. Additionally, metrological devices may produce analog data and digital data. In at least some examples, metrological devices may produce complex data which requires computation to decode into physical measurement data (or primary asset data, as described above.)

As used herein, the term “computer” and related terms, e.g., “computing device,” are not limited to integrated circuits referred to in the art as a computer, but broadly refers to a microcontroller, a microcomputer, a programmable logic controller (PLC), an application specific integrated circuit, and other programmable circuits, and these terms are used interchangeably here. As used herein, “computing device” also includes cloud “computing devices,” which refer to a computer architecture allowing for the use of multiple heterogeneous computing devices for data storage, retrieval, and processing. The heterogeneous computing devices may use a common network or a plurality of networks so that some computing devices are in networked communication with one another over a common network but not all computing devices. In other words, a plurality of networks may be used in order to facilitate the communication between and coordination of all computing devices. As used herein, “computing device” may also refer to any computing device that may be used in a portable manner including, but not limited to, smart phones, personal digital assistants (“PDAs”), computer tablets, hybrid phone/computer tablets (“Phablet”), or other similar devices. In some examples, the computing device may include a variety of peripherals and accessories including, without limitation, microphones, speakers, keyboards, touchscreens, gyroscopes, accelerometers, and metrological devices. As used herein, the computing device may be portable or mobile.

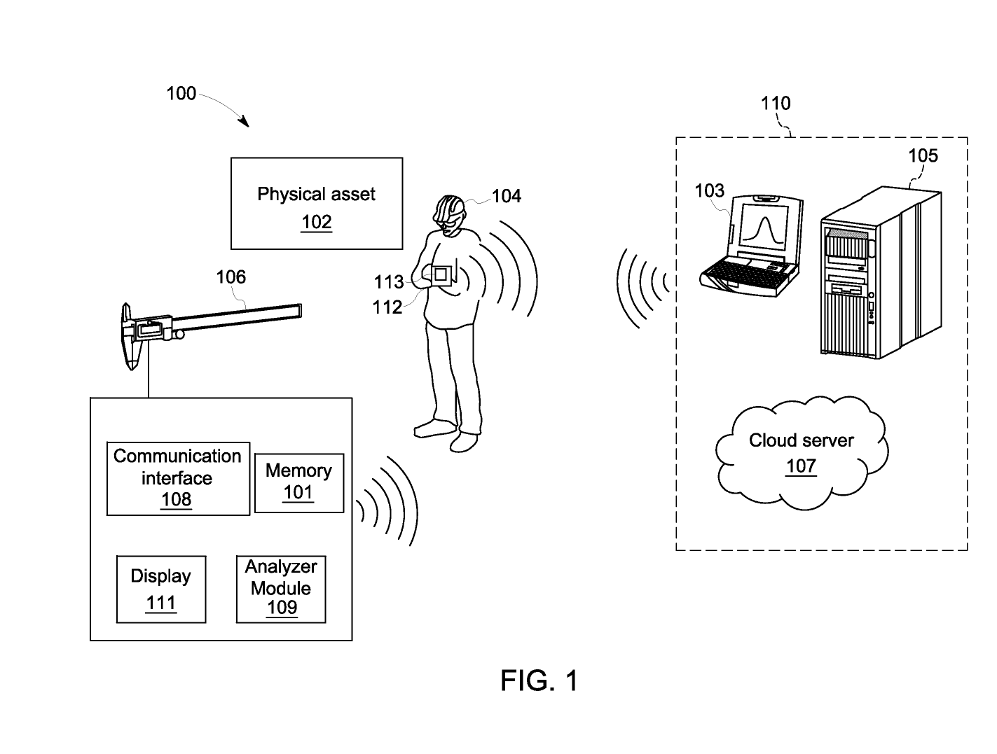

Turning to FIG. 1, a schematic diagram of an example environment 100 containing physical assets 102, being monitored by a user (e.g., field inspector) 104 is provided. Although the environment 100 includes one physical asset 102, the systems and methods described herein may be applied to any environment 100 containing any number or variety of physical assets 102. Some examples of environments include industrial environments, power generation and distribution environments, manufacturing environments, biotechnology environments, commercial sales environments, commercial distribution environments, transportation environments, residential environments, and agricultural environments. Other suitable environments may be used.

The user 104 may use a metrological device 106 to take physical measurements and obtain asset data from the physical assets 102. In some embodiments, the metrological device 106 may be configured to obtain at least one kind of asset data. For example, the metrological device 106 may be at least one of a taper gauge, a digital indicator, calipers, a micrometer, a depth gauge, a protractor, a digital voltmeter, etc. and may be configured to take measurements equivalent to a caliper, or pressure measurements, fluid level measurements, temperature readings, etc. In one or more embodiments, the metrological device 106 may store the data in a memory 101.

In one or more embodiments, the metrological device 106 may include at least one interface 108 that allows the device 106 to transmit asset data to another device, and receive data and instructions. The metrological device 106 may use a variety of wireless communication protocols to transmit data and receive data via their respective output interfaces, as further described below.

The environment 100 may also include one or more computing devices 110, such as a recording computing device 103, a server 105, or a cloud server 107, for example.

The environment 100 may also include a hands-free communication device 112. In one or more embodiments, the hands-free communication device 112 may receive data, and may include an interface to allow the user 104 to transmit data, as will be further described below. As described above, the hands-free communication device 112 may be a wrist-worn smart watch, a heads up display (HUD) (e.g., Google Glass), a body-worn display, a detached display mounted somewhere other than the metrological device but easily accessible by the single user, a speaker, a light feedback module, a haptic feedback module (e.g., vibration motor), or any other suitable hands-free communication device 112.

As depicted, various elements are in wireless communication with each other. Any suitable wireless protocol may be used (e.g., BlueTooth, BlueTooth Smart, BlueTooth Low Energy, WiFi, ANT, UWB, ZigBee, LTE, 6LoWPAN, WiMax).

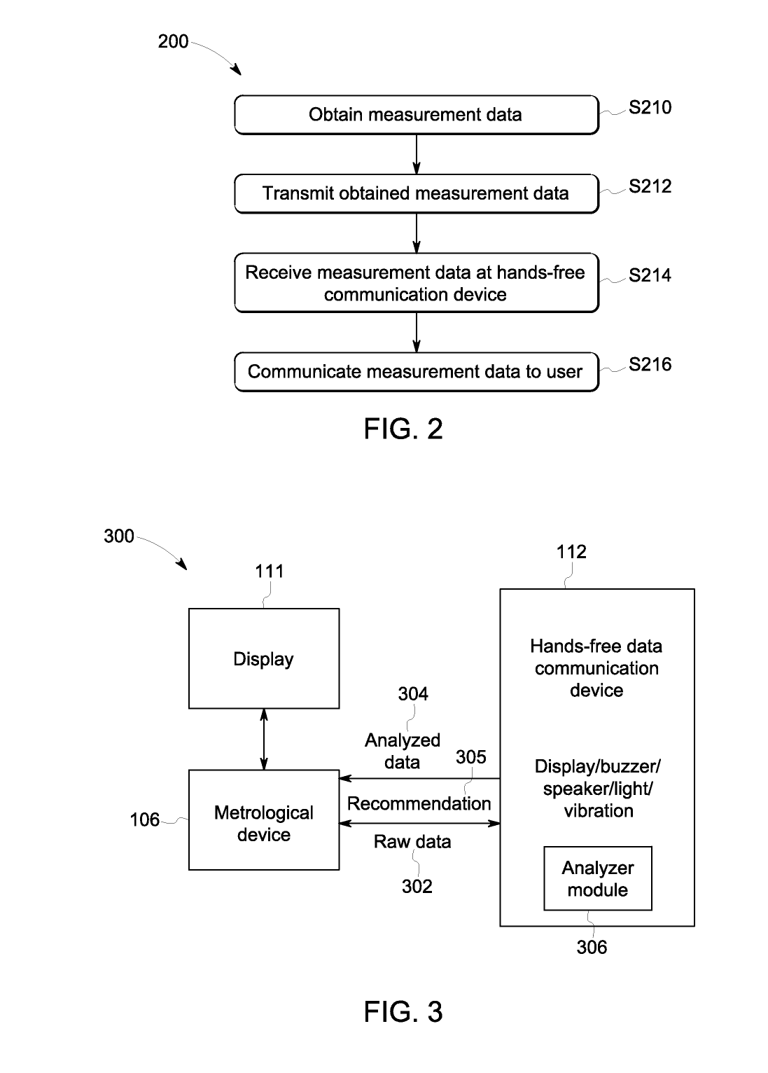

Turning to FIGS. 2-3, is an example of operation according to some embodiments. In particular, FIG. 2 is a flow diagram of a process 200 according to some embodiments. Process 200 and other processes described (e.g., process 400) herein may be performed using any suitable combination of hardware (e.g., circuit(s)), software or manual means. In one or more embodiments, a system 300 (FIG. 3) or system 500 (FIG. 5) is conditioned to perform the process 200 and 400, respectively, such that the system is a special-purpose element configured to perform operations not performable by a general-purpose computer or device. Software embodying these processes may be stored by any non-transitory tangible medium including a fixed disk, a floppy disk, a CD, a DVD, a Flash drive, or a magnetic tape. Examples of these processes will be described below with respect to embodiments of the system, but embodiments are not limited thereto.

Initially, at S210, the metrological device 106 obtains a measurement (e.g., “measurement data”) of the physical asset 102. The measurement may be obtained via conventional operation of the metrological device 106. In some embodiments, the metrological device 106 may provide the obtained measurement data to a display 111 of the measurement device 106. Then in S212, the metrological device 106 transmits the obtained measurement data. In one or more embodiments, the measurement data may be transmitted wirelessly. In one or more embodiments, the obtained measurement data is “raw” data in that it has not been analyzed or manipulated. The obtained raw measurement data 302 is received at the hands-free communication device 112 in S214. In one or more embodiments, the transmitted and received data may be sent directly from the metrological device 106 to the hands-free communication device 112 without the use of an external adaptor providing a communication channel. Then the measurement data 302 is communicated to the user 104 in S216 via the hands-free communication device 112. The measurement data 302 may be communicated to the user 104 via at least one of visually, audibly or in a haptic manner. For example, if the hands-free communication device 112 is a wrist-watch, the hands-free communication device may display the data (visually), may speak the data or generate a noise (audible) to indicate the data is available, or may vibrate (haptic) to indicate the data or indicate the data is available.

In some embodiments, the raw data is communicated to the user 104, while in other embodiments, the raw data is analyzed prior to communication to the user 104, such that the user 104 receives analyzed data 304 in addition to or instead of the raw data. In one or more embodiments, the hands-free communication device 112 may include an analyzer module 306 that may analyze the raw data. Examples of methods of analyzing the data include, for example, numerical calculations, numerical analysis, pattern recognition and modeling. Other suitable types of analyses may be used. In one or more embodiments, the analyzer module 306 may use external data (e.g., models or historic data) to analyze the received raw data. For example, if the measurement is temperature, the analyzer module 306 may compare the received temperature to a previous temperature or a threshold value. As another example, raw sensor data from a linear encoder is received by the analyzer module 306. The analyzer module 306 then processes, linearizes and derives a position from the raw sensor data based on calibration data for the particular sensor that accumulated the data. In some embodiments, the analyzer module 306 may generate a recommendation based on the analyzed data. The recommendation may include at least one of an indication of whether the measurement was within spec and a suggestion for a next step (e.g., re-do the last measurement, skip several measurements, move to a particular measurement, confirm the measurement with another tool). For example, the analyzer module 306 may recommend further measurements be taken with the metrological device 106, or an alert be activated when a measurement exceeds a threshold value, for example. In one or more embodiments, the analyzed data 304 and/or recommendation 305 may also be sent to the metrological device 106 and displayed on the display 111 of the measurement device 106. In one or more embodiments the raw data may be transmitted back to the metrological device 112 with the analyzed data 304 and/or the recommendation 305.

In some embodiments, the hands-free communication device 112 may transmit the data to another device prior to, after, or at substantially the same time as communicating the data to the user 104. For example, the hands-free communication device 112 may communicate the data (raw or analyzed) to the computing device 110 or any other suitable device, at substantially the same time as providing the data on a display 113 associated with the hands-free device 112. Benefits of transmitting the data to another device are the ability to display data to several users at the same time, allowing supervisors to monitor data values without disturbing the measurement task, allowing data to be used for several different purposes at the same time (e.g., filling in a spreadsheet for a record and automatically updating values in a dynamic model on another computer.)

In some embodiments, the user 104 may at least one of accept or decline at least one of the measurement data (raw or analyzed) and the recommendation via the hands-free communication device 112. In one or more embodiments, the user 104 may provide other feedback via the hands-free communication device 112. In one or more embodiments, if the user 104 accepts the measurement data (raw and/or analyzed) and/or the recommendation, the measurement data (raw and/or analyzed) and/or the recommendation is stored in a memory. As described above, the memory may be associated with at least one of the metrological device 106, the hands-free communication device 112, the computing device 110 or any other suitable device.

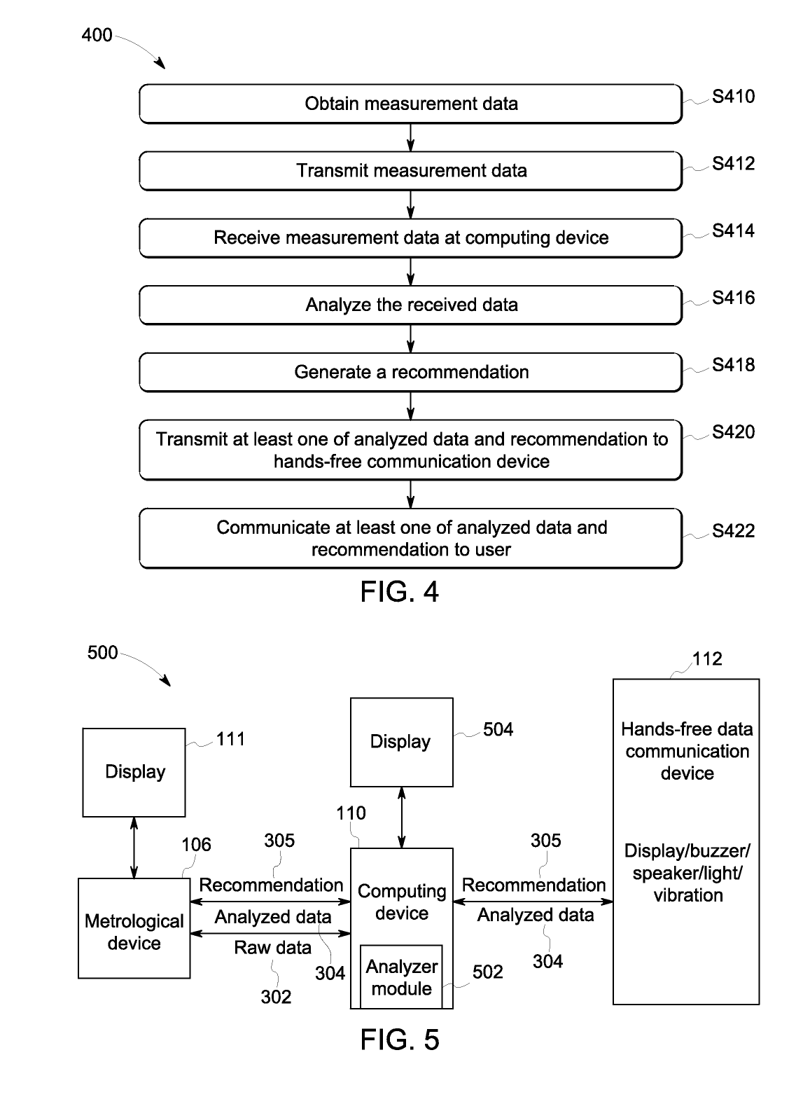

Turning to FIGS. 4 and 5, another example of operation according to some embodiments is provided. In particular, FIG. 4 is a process 400 of operation according to some embodiments. Initially, at S410, the metrological device 106 obtains a measurement (e.g., “measurement data”) of the physical asset 102. The measurement may be obtained via conventional operation of the metrological device 106. In some embodiments, the metrological device 106 may provide the obtained measurement data to the display 111 of the measurement device 106. Then in S412, the metrological device 106 transmits the obtained measurement data. The obtained raw measurement data 302 is received at the computing device 110 in S414. The computing device 110 may be separate from the hands-free communication device 112, and may include an analyzer module 502, similar to the analyzer module 306 described above with respect to FIG. 3, to analyze and/or process the data in S416. Examples of methods of processing the data include, for example, numerical calculations, numerical analysis, pattern recognition and modeling. Other suitable types of analyses may be used. In one or more embodiments, the analyzer module 502 may use external data (e.g., models or historic data) to analyze the received raw data. For example, if the measurement is temperature, the analyzer module 502 may compare the received temperature to a previous temperature or a threshold value. As another example, raw sensor data from a linear encoder is received by the analyzer module 502. The analyzer module 502 then processes, linearizes and derives a position from the raw sensor data based on calibration data for the particular sensor that accumulated the data. In some embodiments, the analyzer module 502 may generate a recommendation based on the analyzed data. In one or more embodiments, the analyzer module 502 may generate a recommendation based on the analyzed data in S418. The recommendation may include at least one of an indication of whether the measurement was within spec and a suggestion for a next step (e.g., re-do the last measurement, skip several measurements, move to a particular measurement, confirm the measurement with another tool). For example, the analyzer module 502 may recommend further measurements be taken with the metrological device 106, or an alert be activated when a measurement exceeds a threshold value, for example. Then in S420, at least one of the analyzed data 304 and a recommendation 305 may be transmitted to the hands-free communication device 112, and communicated to the user 104 in S422. In one or more embodiments, at least one of the analyzed data 304 and recommendation 305 may be displayed on a display 504 of the computing device 110, before, after, or at substantially the same time as the analyzed data is transmitted to the hands-free communication device 112. In one or more embodiments, at least one of the analyzed data 304 and recommendation 305 may be displayed on the display 111 of the metrological device 106. In one or more embodiments the raw data may be transmitted back to the metrological device 106 for display on the display 111 associated therewith, together with at least one of the analyzed data 304 and/or the recommendation 305.

As described above, with reference to FIG. 2, in some embodiments, the user 104 may at least one of accept or decline at least one of the measurement data (raw or analyzed) and the recommendation via the hands-free communication device 112. In one or more embodiments, the user 104 may provide other feedback via the hands-free communication device 112. In one or more embodiments, if the user 104 accepts the measurement data (raw and/or analyzed) and/or the recommendation, the measurement data (raw and/or analyzed) and/or the recommendation is stored in a memory. As described above, the memory may be associated with at least one of the metrological device 106, the hands-free communication device 112, the computing device 110 or any other suitable device.

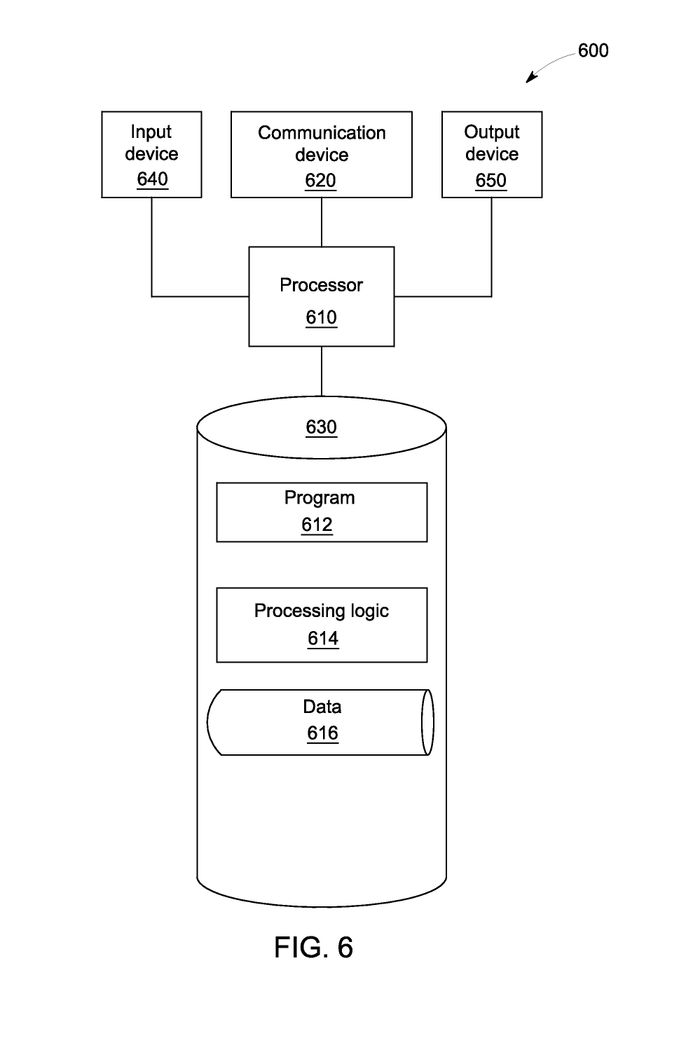

Note the embodiments described herein may be implemented using any number of different hardware configurations. For example, FIG. 6 illustrates a hands-free metrological communication processing platform 600 that may be, for example, associated with the system 300 of FIG. 3 or the system 500 of FIG. 5. The hands-free metrological communication processing platform 600 comprises a hands-free metrological communication platform processor 610 (“processor”), such as one or more commercially available Central Processing Units (CPUs) in the form of one-chip microprocessors, coupled to a communication device 620 configured to communicate via a communication network (not shown in FIG. 6). The communication device 620 may be used to communicate, for example, with one or more users. The hands-free metrological communication processing platform 600 further includes an input device 640 (e.g., a mouse and/or keyboard to enter information about the measurements and/or assets) and an output device 650 (e.g., to output and display the data and/or recommendations).

The processor 610 also communicates with a memory/storage device 630. The storage device 630 may comprise any appropriate information storage device, including combinations of magnetic storage devices (e.g., a hard disk drive), optical storage devices, mobile telephones, and/or semiconductor memory devices. The storage device 630 may store a program 612 and/or hands-free metrological communication processing logic 614 for controlling the processor 610. The processor 610 performs instructions of the programs 612, 614, and thereby operates in accordance with any of the embodiments described herein. For example, the processor 610 may receive measurement data and then may apply the analyzer module 306/502 via the instructions of the programs 612, 614 to generate analyzed data 304 and/or a recommendation 305.

The programs 612, 614 may be stored in a compressed, uncompiled and/or encrypted format. The programs 612, 614 may furthermore include other program elements, such as an operating system, a database management system, and/or device drivers used by the processor 610 to interface with peripheral devices.

As used herein, information may be “received” by or “transmitted” to, for example: (i) the platform 600 from another device; or (ii) a software application or module within the platform 600 from another software application, module, or any other source.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should be noted that any of the methods described herein can include an additional step of providing a system comprising distinct software modules embodied on a computer readable storage medium; the modules can include, for example, any or all of the elements depicted in the block diagrams and/or described herein; by way of example and not limitation, an analyzer module. The method steps can then be carried out using the distinct software modules and/or sub-modules of the system, as described above, executing on one or more hardware processors 610 (FIG. 6). Further, a computer program product can include a computer-readable storage medium with code adapted to be implemented to carry out one or more method steps described herein, including the provision of the system with the distinct software modules.

This written description uses examples to disclose the invention, including the preferred embodiments, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. Aspects from the various embodiments described, as well as other known equivalents for each such aspects, can be mixed and matched by one of ordinary skill in the art to construct additional embodiments and techniques in accordance with principles of this application.

Those in the art will appreciate that various adaptations and modifications of the above-described embodiments can be configured without departing from the scope and spirit of the claims. Therefore, it is to be understood that the claims may be practiced other than as specifically described herein.

1. A system comprising:
a metrological device operative to obtain and transmit measurement data; and
a hands-free communication device operative to receive the obtained data and communicate the data to a user.

2. The system of claim 1, further comprising:
an analyzer module operative to:
receive the obtained data prior to communication to the user,
analyze the obtained data, and
communicate the analyzed data to the user.

3. The system of claim 2, wherein the hands-free communication device includes the analyzer module.

4. The system of claim 2, wherein the analyzer module receives the obtained data from the metrological device, and is further operative to transmit the analyzed data to the hands-free communication device for communication to the user.

5. The system of claim 2, wherein the analyzer module is operative to generate a recommendation, based on the analyzed data, and communicate the recommendation to the user.

6. The system of claim 1, wherein the measurement data is transmitted wirelessly to the hands-free communication device.

7. The system of claim 1, wherein the communication to the user is one of visual, audible or haptic.

8. The system of claim 1, wherein the metrological device is operative to detect metrological data from a physical asset.

9. The system of claim 1, wherein the hands-free communication device is at least one of a smart-watch, a heads up display, a body-worn display, a detached display, and a speaker.

10. The system of claim 1, wherein the measurement data is at least one of distance, angle, thickness, pressure, voltage current, and raw data.

11. The system of claim 1, wherein the hands-free communication device communicates the obtained data to the user while the metrological device is maintained in situ.

12. The system of claim 1, wherein the metrological device comprises one of a taper gauge, calipers, a micrometer, a depth gauge, a protractor and a digital voltmeter.

13. A method comprising:
obtaining measurement data with a metrological device;
transmitting the obtained measurement data;
receiving the obtained measurement data at a hands-free communication device; and
communicating the obtained measurement data to a user.

14. The method of claim 13, further comprising:
analyzing the data, via an analyzer module at the hands-free communication device, prior to communicating the obtained measurement data to the user.

15. The method of claim 14, further comprising:
generating a recommendation based on the analyzed data; and
communicating the recommendation to the user.

16. The method of claim 13, further comprising:
transmitting the obtained data from the metrological device to an analyzer module;
analyzing the obtained data with the analyzer module; and
transmitting the analyzed data to the hands-free communication device for communication to the user.

17. The method of claim 16, wherein the analyzer module is separate from the hands-free communication device.

18. The method of claim 16, further comprising:
generating a recommendation, via the analyzer module, based on the analyzed data; and
transmitting the recommendation to the hands-free communication device.

19. The method of claim 13, wherein receiving the measurement data at the hands-free communication device further comprises:
wirelessly transmitting the measurement data to the hands-free communication device.

20. The method of claim 13, wherein the communication to the user is at least one of visual, audible or haptic.
